(19) United States
(12) Patent Application Publication
(10) Pub. No.: US 2007/0023787 A1
(43) Pub. Date: Feb. 1, 2007

(54) Drive unit for charge coupled devices and driving method for charge coupled devices

(76) Inventor: Akihiro Kuroda, Anpachi-Gun (JP)

Correspondence Address: CANTOR COLBURN, LLP, 55 GRIFFIN ROAD SOUTH, BLOOMFIELD, CT, 06002, US

(21) Appl. No.: 11/495,288

(22) Filed: Jul. 28, 2006

(30) Foreign Application Priority Data
Jul. 28, 2005 (JP) 2005-219308

(51) Int. Cl. H01L 29/768

(52) U.S. Cl. 257/238

(57) ABSTRACT

A drive unit for a charge coupled device, which includes a plurality of transfer electrodes arranged to intersect a transfer direction of information charge, and stores and transfers information electric charge using potential wells formed in a semiconductor substrate by voltages applied to the transfer electrodes. As at least one of the transfer electrodes is used as a selected transfer electrode, the drive unit causes the at least one transfer electrode to undergo a cycle of switching from an ON state to an OFF state a number of times continuously to transfer the information electric charge.

### CROSS-REFERENCE TO RELATED APPLICATIONS

The entire disclosure of Japanese Patent Application No. 2005-219308 including specification, claims, drawings, and abstracts is incorporated herein by reference.

### BACKGROUND OF THE INVENTION

1. Field of the Invention

The present invention relates to a drive unit for charge coupled devices with improved transfer efficiency of information charge and a method for driving the charge coupled devices.

2. Description of the Related Art

The CCD solid-state imaging apparatus is in widespread use, which includes charge coupled devices for generating information charge by photoelectric conversion at pixels on which light is incident from outside, and storing and transferring the information charge by using potential wells formed in a semiconductor substrate using voltages applied to transfer electrodes.

As shown in FIG. 8, a frame-transfer-type-CCD solid-state image sensing device 10 includes an image capture section 10i, a storage section 10s, a horizontal transfer section 10h, and an output section 10d. The image capture section 10i includes a plurality of rows of vertical shift registers. The vertical shift registers of the image capture section 10i include matrix-arranged light-receiving pixels for receiving external light and generating information charge in an amount corresponding to the intensity of the incident light. As a vertical clock pulse is input from an external driver circuit to the image capture section 10i, the information charge generated at the individual light-receiving pixels is transferred along the vertical shift registers to the storage section 10s. In a color-picture CCD solid-state image sensing device, each light-receiving pixel of the image sensing device 10i is covered with a transmission filter for one of wavelengths of red (R), green (G), and blue (B). Normally, the transmission filters are arranged in a mosaic pattern. For example, on the odd-number rows of the vertical shift registers, the information charges corresponding to red (R) and blue (B) are transferred alternately. On the even-number rows of the vertical shift registers, the information charges corresponding to green (G) and blue (B) are transferred alternately. The storage section 10s has the vertical shift registers arranged to be continuous from the vertical shift registers of the image sensing section 10i. The vertical shift registers of the storage section 10s are shielded from light and used to store information charge for one frame. Vertical clock pulses and control clock pulses are input to the storage section 10s from the driver circuit. As a vertical clock pulse and an output control clock pulse are applied, the information charges held in the storage section 10s are transferred one line after another to the horizontal transfer section 10h that includes a horizontal shift register. The information charge for one pixel of each vertical shift register of the storage section 10s is transferred sequentially to one bit of the horizontal shift register of the horizontal transfer section 10h. A horizontal clock pulse is input from the driver circuit to the horizontal transfer section 10h. In the horizontal transfer section 10h, each time a horizontal clock pulse is received, the information charge is transferred in units of charge for one pixel to the output section 10d. The output section 10d converts information charge per pixel into a voltage value, and changes in voltage value are used as an output signal.

However, there is a problem of lowering of the information charge transfer efficiency, more specifically, a problem that the information charges are unable to be transferred successfully at the interface portion from the image capture section 10i to the storage section 10s or at the interface portion from the storage section 10s to the horizontal transfer section 10h and remain in potential wells at the preceding stage of the storage section. The decrease in the transfer efficiency of information charge gives rise to, for example, a mixture of information charges of different colors in a device which has the pixels of multiple colors arranged in the same row, resulting in a degraded distinction of the hues of colors in output images. If the transfer efficiency of information charge varies among different rows of the vertical shift registers, noise caused by a color mixture occurs which extends in the vertical direction of output images.

### SUMMARY OF THE INVENTION

According to the present invention, there is provided a drive unit for a charge coupled device, which includes a plurality of transfer electrodes arranged to intersect a transfer direction of information charge, for storing and transferring information by using potential wells formed in a semiconductor substrate using voltages applied to the transfer electrodes, wherein at least one of the transfer electrodes is used as a selected transfer electrode. The drive unit applies a voltage to the at least one selected transfer electrode in a cycle of switching from an ON state to an OFF state a number of times continuously to thereby transfer the information charge.

### BRIEF DESCRIPTION OF THE DRAWINGS

Preferred embodiments of the present invention will be described in detail based on the following drawings, wherein:

FIG. 1 is a block diagram showing a structure of a solid-state image sensing device according to an embodiment of the present invention;

FIG. 2 is a plan view showing vertical shift registers of an image capture section and a storage section according to the embodiment of the present invention;

FIG. 3 is a plan view showing a structure of a storage section and a horizontal transfer section according to the embodiment of the present invention;

FIG. 4 is a sectional view showing a structure of a storage section and a horizontal transfer section according to the embodiment of the present invention;

FIG. 5 is a timing chart for explaining a method of controlling transfer electrodes according to the embodiment of the present invention;

FIG. 6 is a schematic diagram showing potentials at the transfer electrode according to the embodiment of the present invention;

FIG. 7 is a diagram showing potentials for explaining a presumed principle in the present invention;

FIG. 8 is a diagram showing a structure of a solid-state image sensing device in the background art; and

FIG. 9 is diagram for explaining a problem.

### DESCRIPTION OF THE PREFERRED EMBODIMENTS

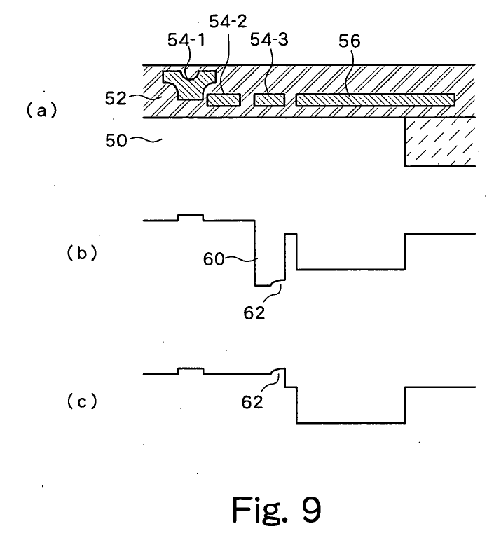

Referring to FIG. 9, the cause of a decrease in the transfer efficiency will be described below. FIGS. 9(a) to 9(c) show, as a conventional example, the interface portion from the storage section 10s to the horizontal transfer section 10h. FIG. 9(a) is a schematic sectional view of the device at a section where it has an interface from the storage section 10s to the horizontal transfer section 10h. An insulation film 52 is formed on the surface of the semiconductor substrate 50. On the insulation film 52, transfer electrodes 54-1 to 54-3 of the vertical shift register are arranged in a direction perpendicular to the plane of the paper, and a transfer electrode 56 of the horizontal shift register is arranged in a direction in the plane of the paper. In this case, because of displacement of alignment between the doped region of the semiconductor substrate and the transfer electrode 54-3 as the final stage of the vertical shift registers, for example, an energy barrier 62 may occur in a potential well 60 formed under the transfer electrode 54-3 at the interface portion, such as a notch or a spike which obstructs the flow of charge in the charge transfer direction as shown in FIG. 9(b). When the transfer electrode 54-3 is turned off, the energy barrier 62 acts as a barrier against the transfer of information charge from the vertical shift register to the horizontal shift register as shown in FIG. 9(c), and is considered to reduce the transfer efficiency of information charge.

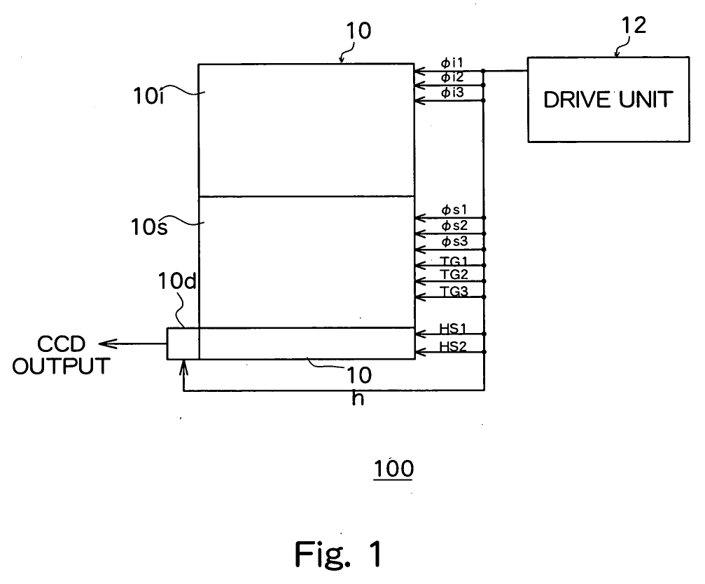

A solid-state imaging apparatus 100 according to an embodiment of the present invention is formed by including a solid-state image sensing device 10 and a drive unit 12 (driver circuit) as shown in FIG. 1. The solid-state image sensing device 10 includes a plurality of transfer electrodes arranged to intersect the transfer direction of information charge, and also includes a charge transfer device, such as a charge coupled device (CCD) which stores and transfers information charge by using potential wells formed in the semiconductor substrate by voltages applied to the transfer electrodes. The solid-state image sensing device 10, which is connected to the drive unit 12, stores and transfers information charge on receiving various clock pulses (control signals) from the drive unit 12.

For example, the frame-transfer-type-CCD solid-state image sensing device 10 includes an image capture section 10i, a storage section 10s, a horizontal transfer section 10h, and an output section 10d.

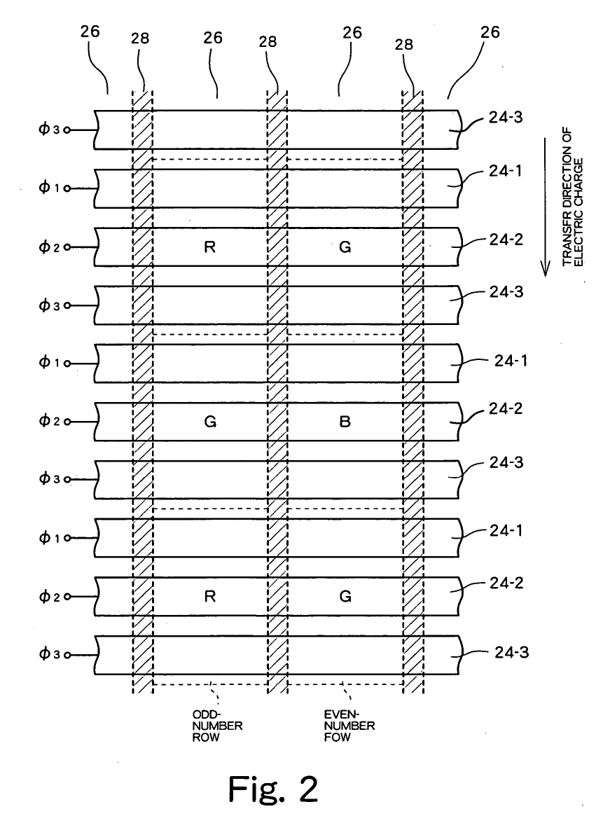

The image capture section 10i and the storage section 10s each include vertical shift registers formed on the surface region of the semiconductor substrate as shown in the plan view of the device interior in FIG. 2. The image capture section 10i includes a plurality of rows of vertical shift registers. The vertical shift registers of the image capture section 10i include matrix-arranged light-receiving pixels for generating information electric charges in amounts corresponding to the intensities of incident light. In a color-picture CCD solid-state image sensing device, each of the light-receiving pixels of the image capture section 10i is covered with one of the transmission filters corresponding to wavelengths of red (R), green (G), and blue (B). Normally, the transmission filters are arranged in a mosaic pattern. For example, on each odd-number row of the vertical shift register, the red (R) and green (G) filters are arranged alternately, and information charges corresponding to red (R) and green (G) are transferred alternately, and on each even-number row of the vertical shift register, the green (G) and blue (B) filters are arranged alternately, and information charges corresponding to green (G) and blue (B) are transferred alternately. The storage section 10s has vertical shift registers arranged to be continuous to the vertical shift registers of the image capture section 10i. The storage section 10s includes a number of transfer stages of the vertical shift registers to store information charges corresponding to one frame of the image capture section 10i. The vertical shift registers of the storage section 10s are entirely shielded from light.

The vertical shift register is formed as described below. Each P-well (PW) as a P-type diffusion layer is formed in an N-type semiconductor substrate. An N-well as N-type diffusion layer is formed in the top region of the P-well. Separation regions 28 doped with P-type impurities are provided, mutually parallel and separated a predetermined distance from each other, along the extending direction of the vertical shift registers. The above-mentioned N-wells are electrically partitioned by adjacent separation regions 28. The regions between the separation regions 28 are referred to as the channel regions 26, which serve as transfer paths of information charges. A potential barrier is formed in each separation region 28 between the adjacent channel regions and electrically separates the channel regions 26. In addition, an insulation film is formed on the surface of the semiconductor substrate. On this insulation film, a plurality of transfer electrodes 24-1 to 24-3 of a polysilicon film are arranged in parallel and in a manner to intersect the channel regions 26.

In the embodiment of the present invention, a set of three continuous transfer electrodes 24-1, 24-2, and 24-3 constitutes one light receiving pixel. By raising a set of transfer electrodes 24-1, 24-2, and 24-3 to high potentials, a potential well can be formed in the channel regions 26 of the semiconductor substrate.

When taking a picture, with one of a set of transfer electrodes 24-1, 24-2, and 24-3 held at a high potential, information charges generated by photoelectric conversion at the respective pixels are stored in the potential wells. When transferring the electric charges, by applying transfer clock pulses φi1 to φi3 of predetermined periods to a set of transfer electrodes 24-1, 24-2, and 24-3 respectively, the information charges generated at the image capture section 10i are transferred sequentially in the vertical transfer direction to the storage section 10s.

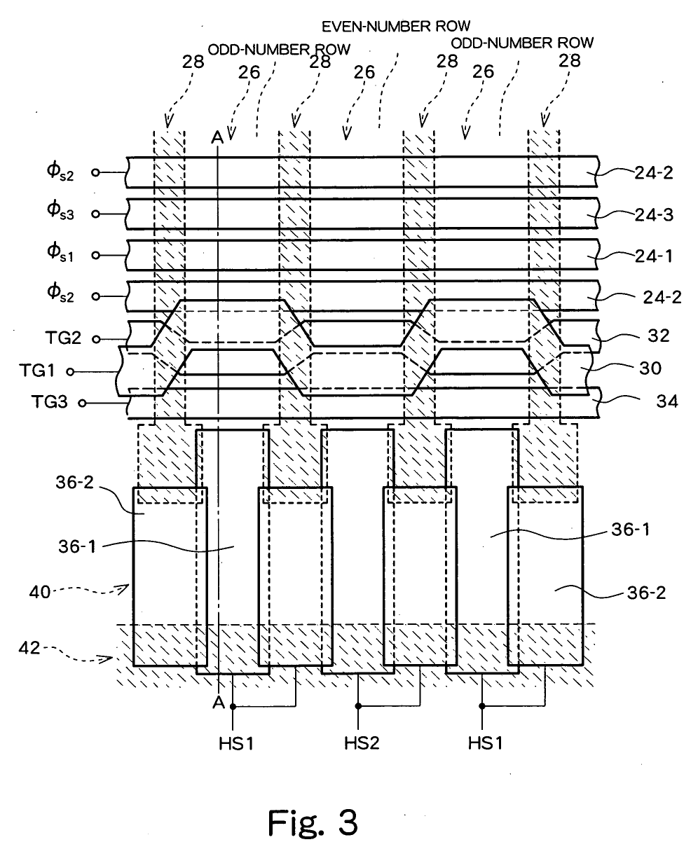

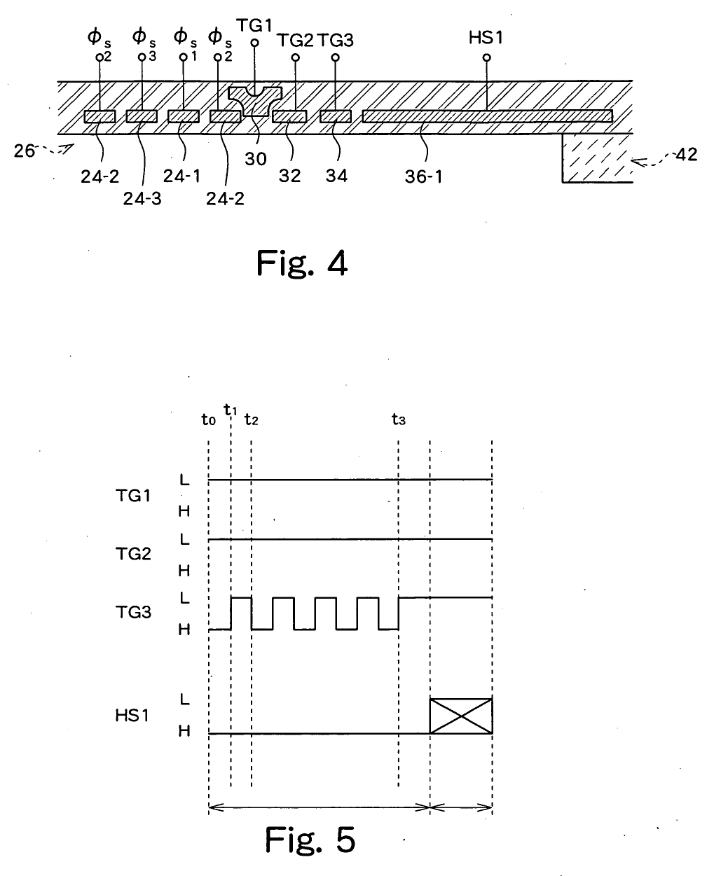

FIG. 3 is a plan view of the inside structure of the device at the interface portion between the storage section 10s and the horizontal transfer section 10h. FIG. 4 is a sectional view showing a cross-section structure of the device taken along line A-A in FIG. 3.

A first output transfer electrode 30 is arranged in parallel with the transfer electrodes 24-1 to 24-3 on the output side of the vertical shift registers. The first output transfer electrode 30 meanders in such a way as to be away from the horizontal transfer section 10h when it intersects the odd-number rows, and closer to the horizontal transfer section 10h when it intersects the even-number rows. In contrast to the first output transfer electrode 10, a second output transfer electrode 32 is arranged, over the separation regions, to go across the first output transfer electrode 30 via an insulation film. More specifically, the second output transfer electrode 32 meanders in such a way as to be closer to the horizontal transfer section 10h when it intersects the odd-number rows and further away from the horizontal transfer section 10h. A third output transfer electrode 34 is arranged much closer to the output side than the first output transfer electrode 30 and the second output transfer electrode 32. The third output transfer electrode 34 comes closer to the second output transfer electrode 32 when this electrode intersects the odd-number rows and comes closer to the second output transfer electrode 32 when the electrode intersects the first output transfer electrode 30.

The horizontal transfer section 10h includes a horizontal transfer section 10h which receives and transfers information charges output from the vertical shift registers of the storage section 10s. The horizontal shift register includes a horizontal channel region 40 and horizontal transfer electrodes 36-1 and 36-2. The horizontal channel region 40 is divided in a direction intersecting the extending direction of the vertical shift registers by the separation regions 28 extending from the vertical shift registers of the storage section 10s and also by a horizontal separation region 42 formed as a P-type diffusion region, which is provided facing the storage section 10s. The channel regions 26 of the vertical shift registers are connected to the horizontal channel region 40 of the horizontal shift register through gaps between the extending separation regions 28. The first horizontal transfer electrodes 36-1 are provided on the semiconductor with intervention of an insulation film in a manner as bridging the third output transfer electrode 34 and the horizontal separation region 42. The first horizontal transfer electrodes 36-1 extend to the vicinity of the third output transfer electrode 34 with intervention of an insulation film. Second horizontal transfer electrodes 36-2 are arranged to intersect the horizontal channel region 40 in such a manner that the second horizontal transfer electrodes 36-2 cover the gaps between the first horizontal transfer electrodes 36-1 and the first and second horizontal transfer electrodes 36-2 and 36-1 partially overlap each other with an insulation layer provided between them.

Vertical clock pulses φs1 to φs3 are applied by the drive unit 12 to the transfer electrodes 24-1 to 24-3. Therefore, the information charges transferred from the image capture section 10i and buffered in the storage section 10s are sent sequentially in the vertical transfer direction. Output control clock pulses TG1 and TG2 are applied from the drive unit 12 to the first and second output transfer electrodes 30, 32. Moreover, an output control clock pulse TG3, controllable independently of output control clock pulses TG1 and TG2, is applied from the drive unit 12 to the third output transfer electrode 34.

The output control clock pulses TG1, TG2, and TG3 applied to the output transfer electrodes 30, 32, and 33 may be made controllable independently of the vertical clock pulses φs1 to φs3. In this case, information charges can be transferred to the horizontal shift register alternately from the odd-number rows and the even-number rows of the vertical shift registers. For example, when taking color pictures, it is possible to prevent a mixture of information charges corresponding to different wavelength components (different colors) in the horizontal shift register.

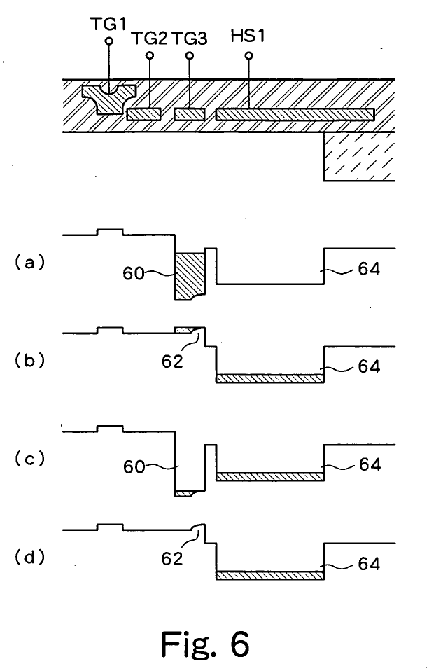

FIG. 5 is a timing chart of output control clock pulses TG1, TG2, and TG3, and a horizontal clock pulse HS1 when information charges are transferred vertically from the odd-number rows of the vertical shift registers to the horizontal shift register, which are shown in a cross section in FIG. 4, taken along line A-A in FIG. 3. In the initial state (at time t0), an output control clock TG3 applied to the third output transfer electrode 34 is at a high level (H), and as shown in FIG. 6(a), information charge is transferred to the potential well 50 already formed under the third output transfer electrode 34.

At time t1, while the output control clock pulses TG1, TG2 are held at the low level (L) and the horizontal clock pulse HS1 are held at the high level (H), the electrode 34 is switched from the ON state to the OFF state by changing the horizontal clock pulse applied to the third output transfer electrode 34 from the high level (H) to the low level (L). Accordingly, as shown in FIG. 6(b), the potential well under the third output transfer electrode 34 becomes shallow, so that information charge is transferred into a potential well 64 formed in the horizontal channel region 40.

In this case, an energy barrier 62 sometimes occurs at the interface between the third output transfer electrode 34 and the horizontal shift register as shown in FIG. 6(b), for example, due to displacement of the alignment between the doped region of the semiconductor substrate and the third output transfer electrode 34 at the final stage of the vertical shift registers. The energy barrier 62 as described above acts as a barrier to inhibit the transfer of information charge from the vertical shift register to the horizontal shift register, which is considered to cause a decrease in the transfer efficiency of information charge. At an interface portion between different kinds of shift registers, such as at the interface portion between the image capture section 10i and the storage section 10s, or at the interface portion between the storage section 10s and the horizontal transfer section 10h, if the alignment between the doped region of the semiconductor substrate and the transfer electrodes is displaced, it can have a considerable impact, such as causing deterioration of the transfer efficiency of the information electrode because of the energy barrier 62, and this is a serious problem.

In a period between t2 to t3, while the output control clock pulses TG1 and TG2 are held at the low level (L) and the horizontal clock pulse HS1 is at the high level (H), the output control clock pulse TG3 applied to the third output transfer electrode 34 is repeatedly changed to the high level (H) and the low level (L). In other words, before information charges are transferred from the previous stages, a cycle of switching the third output transfer electrode 34, as the final stage of the vertical shift registers, from the ON state to the OFF state is continuously repeated several times.

Consequently, a cycle is repeated as follows: as shown in FIG. 6(c), a potential well 60 is formed under the third output transfer electrode 34 when in the ON state, and as shown in FIG. 6(d), the potential well 60 under the third output electrode 34 is extinguished when in the OFF state. By repeating this cycle, the information charges remaining under the third output transfer electrode 34 are gradually transferred to the horizontal shift register by the energy barrier 62 at the interface between the third output transfer electrode 34 and the horizontal shift register.

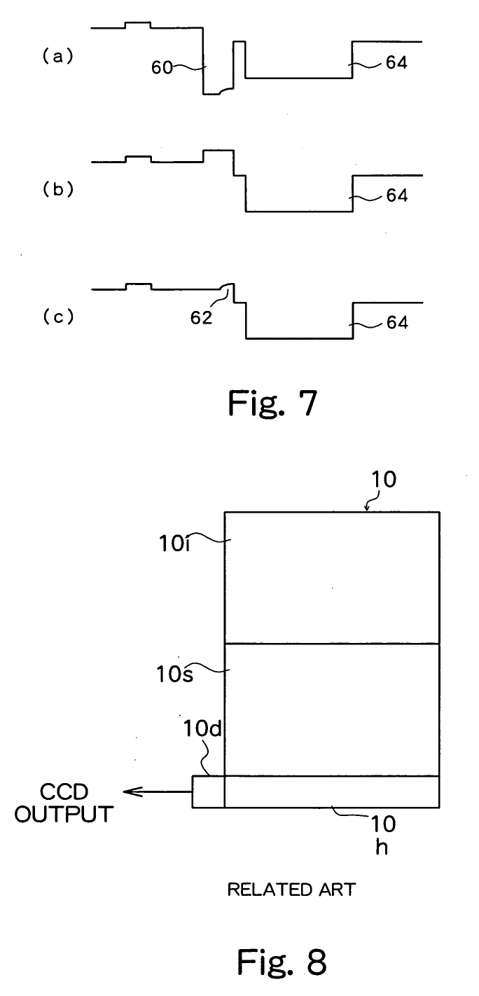

The principle by which information charge is transferred passing over the energy barrier 62 is assumed to be as follows. When an output control clock pulse TG3 applied to the third output transfer electrode 34 is changed from the high level (H) to the low level (L), due, for example to instantaneous overshoot of an output control clock pulse TG3 from a steady state where a potential well is formed as shown in FIG. 7(a) to a steady state where the potential well is extinguished as shown in FIG. 7(c), a condition occurs where the energy barrier 62 lowers as shown in FIG. 7(b). Under the condition that the energy barrier 62 is lowered as described, the information charge that remains below the third output transfer electrode 34 is transferred to the horizontal shift register. Therefore, it is considered that in each cycle that the third output transfer electrode 34 is switched from the ON state to the OFF state, information charge is transferred little by little, and by repeating this cycle, the information charge that remains under the third output transfer electrode 34 can be output to the horizontal shift register more efficiently. Incidentally, the doping density under the first output transfer electrode 30 is made lower to raise the potential barrier. As a result, the remaining electric charge in FIG. 6(b) is prevented from flowing backwards opposite to the transfer direction.

The process of continuously repeating a cycle of switching the transfer electrode on and off before information charges are transferred from the previous stage may be similarly applied to other transfer electrodes. For example, when information charge is transferred from the even-number rows of the vertical shift registers to the horizontal shift register, if the third output transfer electrode 34 at the final stage of the vertical shift registers undergoes a switching cycle from the ON state to the OFF state a number of times continuously, Information charges can be transferred more than before. Also, at the interface portion from the image capture section 10i to the storage section 10s, if the transfer electrode at the final stage of the imaging unit 10i undergoes a switching cycle from the ON state to the OFF state a number of times continuously, information charges can be transferred more efficiently.

As described above, according to this embodiment, the transfer efficiency of information charge in charge coupled devices can be improved. In a solid-state image sensing device having charge coupled devices, the picture quality of output images can be improved. Above all, by inhibiting information charges of different colors from mixing and reducing noise extending in the vertical direction of an output image, the-picture quality of output images can be improved.

In this embodiment, though the CCD solid-state image sensing device of a frame transfer system has been described as an example, the applicable range of the scope of the present invention is not limited to this type of device, but may be applied to types of device which store and transfer electric charges by using potential wells, such as interline-transfer-type-CCD solid-state image sensing device, for example.

1. A drive unit for use with a charge coupled device, including a plurality of transfer electrodes arranged to intersect a transfer direction of information charge, for storing and transferring said information charge by using potential wells formed in a semiconductor substrate by voltages applied to said transfer electrodes, wherein at least one of said transfer electrodes is used as a selected transfer electrode, wherein said drive unit applies a voltage to said at least one selected transfer electrode successively switching from an ON state to an OFF state to thereby transfer said information charge.

2. The drive unit according to claim 1, wherein said charge coupled device further includes a first shift register for transferring information charge in a first transfer direction, and a second shift register for transferring said information charge received from said first shift register, wherein a transfer electrode at a final stage of said first shift register is used as said selected transfer electrode.

3. The drive unit according to claim 1, wherein said charge coupled device further includes a first shift register for transferring information charge in a first transfer direction, and a second shift register for transferring said information charge received from said first shift register in a second transfer direction intersecting said first transfer direction, wherein a transfer electrode at a final stage of said first shift register is used as said selected transfer electrode.

4. The drive unit according to claim 2, wherein said first shift register and said second shift register are formed using different conditions for doping in said semiconductor substrate.

5. The drive unit according to claim 3, wherein said first shift register and said second shift register are formed using different conditions for doping in said semiconductor substrate.

6. The drive unit according to claim 1, wherein said selected transfer electrode can be controlled independently of transfer electrodes other than said selected transfer electrode.

7. The drive unit according to claim 2, wherein said selected transfer electrode can be controlled independently of transfer electrodes other than said selected transfer electrode.

8. The drive unit according to claim 3, wherein said selected transfer electrode can be controlled independently of transfer electrodes other than said selected transfer electrode.

9. The drive unit according to claim 4, wherein said selected transfer electrode can be controlled independently of transfer electrodes other than said selected transfer electrode.

10. A method for driving a charge coupled device, wherein when storing and transferring information charge by forming potential wells in a semiconductor substrate by voltages applied to transfer electrodes, at least one of said transfer electrodes is used as a selected transfer electrode, and said information charge is transferred by applying a voltage to said at least one selected transfer electrode successively switching from an ON state to an OFF state.

11. The method for driving said charge coupled device according to claim 10, wherein said charge coupled device further includes a first shift register for transferring information charge in a first transfer direction, and a second shift register for transferring said information charge received from said first shift register, wherein a transfer electrode at a final stage of said first shift register is used as said selected transfer electrode.

12. The method for driving said charge coupled device according to claim 10, wherein said charge coupled device further includes a first shift register for transferring information charge in a first transfer direction, and a second shift register for transferring said information charge received from said first shift register in a second transfer direction intersecting said first transfer direction, wherein a transfer electrode at a final stage of said first shift register is used as said selected transfer electrode.
